(19) United States
(12) Patent Application Publication
(10) Pub. No.: US 2021/0313335 A1
(43) Pub. Date: Oct. 7, 2021

(54) MEMORY DEVICE

(71) Applicant: Kioxia Corporation, Minato-ku (JP)

(72) Inventors: Kana HIRAYAMA, Yokkaichi Mie (JP); Yasuhiro UCHIYAMA, Yokkaichi Mie (JP); Keisuke NAKATSUKA, Kobe Hyogo (JP)

(73) Assignee: Kioxia Corporation, Minato-ku (JP)

(21) Appl. No.: 17/349,103

(22) Filed: Jun. 16, 2021

Related U.S. Application Data
(63) Continuation of application No. PCT/JP2019/036406, filed on Sep. 17, 2019.

(51) Int. Cl. H01L 27/1157; H01L 27/11519; H01L 27/11524; H01L 27/11551; H01L 27/11565; H01L 27/11578

(52) U.S. Cl. CPC H01L 27/1157; H01L 27/11519; H01L 27/11578; H01L 27/11551; H01L 27/11565; H01L 27/11524

(57) ABSTRACT

According to one embodiment, a memory device includes a plurality of first conductors stacked along a first direction; a second, third, and fourth conductor stacked in a same layer above the first conductors; a plurality of fifth conductors stacked along the first direction; a sixth conductor stacked above the fifth conductors; a first semiconductor extending along the first direction between the second conductor and the sixth conductor; a second semiconductor extending along the first direction between the third conductor and the sixth conductor; and a third semiconductor extending along the first direction between the fourth conductor and the sixth conductor.

### CROSS-REFERENCE TO RELATED APPLICATIONS

This application is a Continuation Application of PCT application No. PCT/JP2019/036406, filed Sep. 17, 2019, the entire contents of which are incorporated herein by reference.

### FIELD

Embodiments described herein relate generally to a memory device.

### BACKGROUND

A memory device capable of storing data in a nonvolatile manner has been known. For such a memory device, a three-dimensional memory structure is being considered in order to achieve high integration and high capacity.

### BRIEF DESCRIPTION OF THE DRAWINGS

FIG. 1 is a block diagram showing a structure of a memory system including a memory device according to a first embodiment.

FIG. 2 is a diagram of a circuit structure showing a memory cell array of the memory device according to the first embodiment.

FIG. 3 is a diagram of a circuit structure showing two memory strings in the memory cell array of the memory device according to the first embodiment.

FIG. 4 is a planar layout of the memory cell array of the memory device according to the first embodiment, as viewed from above.

FIG. 5 is a vertical cross-sectional view of a memory pillar in FIG. 4, taken along line V-V.

FIG. 6 is a traverse cross-sectional view of the memory pillar in FIG. 5, taken along line VI-VI.

FIG. 7 is a vertical cross-sectional view of a hookup region in FIG. 4, taken along line VII-VII.

FIG. 8 is a vertical cross-sectional view of the hookup region in FIG. 4, taken along line VIII-VIII.

FIG. 9 is a schematic diagram of a write operation in the memory device according to the first embodiment.

FIG. 10 is a schematic diagram of a read operation in the memory device according to the first embodiment.

FIG. 11 is a planar layout of the memory cell array when viewed from above, for explaining a manufacturing process of the memory device according to the first embodiment.

FIG. 12 is a vertical cross-sectional view of a cell region in FIG. 11, taken along line XII-XII.

FIG. 13 is a vertical cross-sectional view of the hookup region in FIG. 11, taken along line XIII-XIII.

FIG. 14 is a vertical cross-sectional view of the hookup region in FIG. 11, taken along line XIV-XIV.

FIG. 15 is a planar layout of the memory cell array for explaining a manufacturing process of the memory device according to the first embodiment, as viewed from above.

FIG. 16 is a vertical cross-sectional view of a cell region in FIG. 15, taken along line XVI-XVI.

FIG. 17 is a planar layout of the memory cell array for explaining a manufacturing process of the memory device according to the first embodiment, as viewed from above.

FIG. 18 is a vertical cross-sectional view of a cell region in FIG. 17, taken along line XVIII-XVIII.

FIG. 19 is a planar layout of the memory cell array for explaining a manufacturing process of the memory device according to the first embodiment, as viewed from above,.

FIG. 20 is a vertical cross-sectional view of a hookup region in FIG. 19, taken along line XX-XX.

FIG. 21 is a vertical cross-sectional view of the hookup region in FIG. 19, taken along line XXI-XXI.

FIG. 22 is a planar layout of a memory cell array in a memory device according to a second embodiment, as viewed from above.

FIG. 23 is a vertical cross-sectional view of a hookup region in FIG. 22, taken along line XXIII-XXIII.

FIG. 24 is a planar layout of a memory cell array of a memory device according to a third embodiment, as viewed from above.

FIG. 25 is a vertical cross-sectional view of a hookup region in FIG. 24, taken along line XXV-XXV.

### DETAILED DESCRIPTION

In general, according to one embodiment, a memory device includes a plurality of first conductors stacked along a first direction; a second conductor, a third conductor, and a fourth conductor stacked in a same layer above the first conductors; a plurality of fifth conductors stacked along the first direction; a sixth conductor stacked above the fifth conductors; a first semiconductor extending along the first direction between the second conductor and the sixth conductor; a second semiconductor extending along the first direction between the third conductor and the sixth conductor; and a third semiconductor extending along the first direction between the fourth conductor and the sixth conductor.

The embodiments will be explained below by referring to the drawings. The embodiments exemplify a device and method that realize the technical concept of the invention. The drawings are provided merely for schematic or conceptual purposes, and thus may not be identical to the actual dimensions and proportions. Furthermore, the technical concept of the invention is not limited by the form, structure, arrangement or the like of the structural components.

In the following explanation, components having basically the same functions and structures will be referred to by the same reference numerals. The reference symbols may contain a character string and numerals attached to the character string. When reference symbols containing the same character string are referenced, the corresponding components have the same structure, and are distinguished from each other by the numerals attached to the character strings. When components having reference symbols containing the same character string need not be distinguished from each other, these components may be referred to by a reference symbol containing the character string only.

In the following explanation, a section parallel to a layered surface of a structure on a substrate may be referred to as a “traverse cross section”, and a section intersecting this layered surface may be referred to as a “vertical cross section”.

### 1. First Embodiment

A memory device according to a first embodiment will be explained.

### 1.1 Structure

First, a structure of the memory device according to the first embodiment will be explained.

### 1.1.1 Memory device

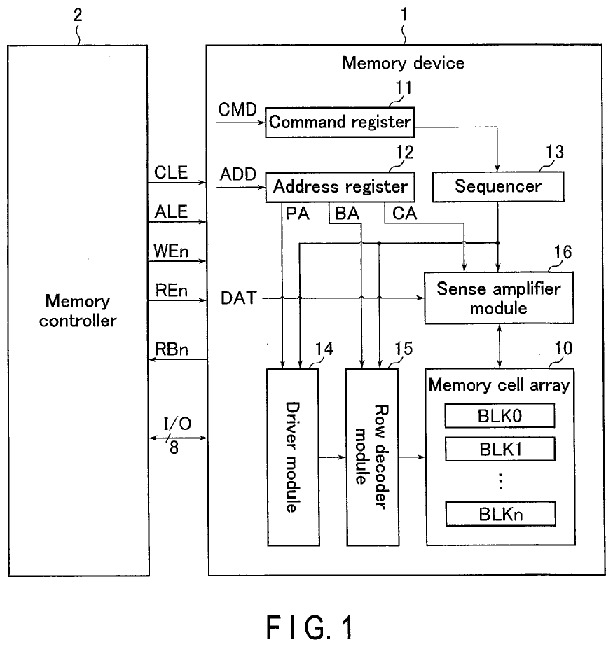

FIG. 1 is a block diagram for explaining a structure of a memory system including the memory device according to the first embodiment. A memory device 1 is a NAND flash memory capable of storing data in a nonvolatile manner, and is controlled by an external memory controller 2. Communications between the memory device 1 and the memory controller 2 may conform to a NAND interface standard.

As illustrated in FIG. 1, the memory device 1 may include a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer larger than or equal to 1). A block BLK is a set including memory cells capable of storing data in a nonvolatile manner, and may be used as a data erase unit. The memory cell array 10 is provided with a plurality of bit lines and word lines. Each memory cell is associated with one bit line and one word line. The structure of the memory cell array 10 will be discussed later in detail.

The command register 11 stores a command CMD that the memory device 1 receives from the memory controller 2. Commands CMD include, for example, instructions to instruct the sequencer 13 to execute a read operation, write operation, erase operation, and the like.

The address register 12 stores address information ADD that the memory device 1 receives from the memory controller 2. The address information ADD may include a block address BA, a page address PA, and a column address CA. The block address BA, page address PA, and column address CA may be used for selection of a block BLK, a word line, and a bit line, respectively.

The sequencer 13 controls the entire operation of the memory device 1. For instance, based on a command CMD stored in the command register 11, the sequencer 13 may control the driver module 14, row decoder module 15, and sense amplifier module 16 to implement a read operation, write operation, and erase operation.

The driver module 14 generates voltages to be used for the read operation, write operation, and erase operation. Then, the driver module 14 applies a generated voltage to the signal line corresponding to the selected word line, based on the page address PA stored in the address register 12.

The row decoder module 15 selects, based on the block address BA stored in the address register 12, the corresponding one of the blocks BLK in the memory cell array 10. Then, the row decoder module 15 transfers, to this selected word line in the selected block BLK, the voltage applied to the signal line corresponding to the selected word line.

In a write operation, the sense amplifier module 16 applies a desired voltage to each bit line in accordance with the write data DAT received from the memory controller 2. In a read operation, the sense amplifier module 16 determines the data stored in a memory cell based on the voltage of the bit line, and transfers the determination result as read data DAT to the memory controller 2.

The above memory device 1 and memory controller 2 may be combined to form a single memory system. Examples for such a memory system include memory cards such as an SD™ card, and a solid state drive (SSD).

### 1.1.2 Circuit Structure of Memory cell Array

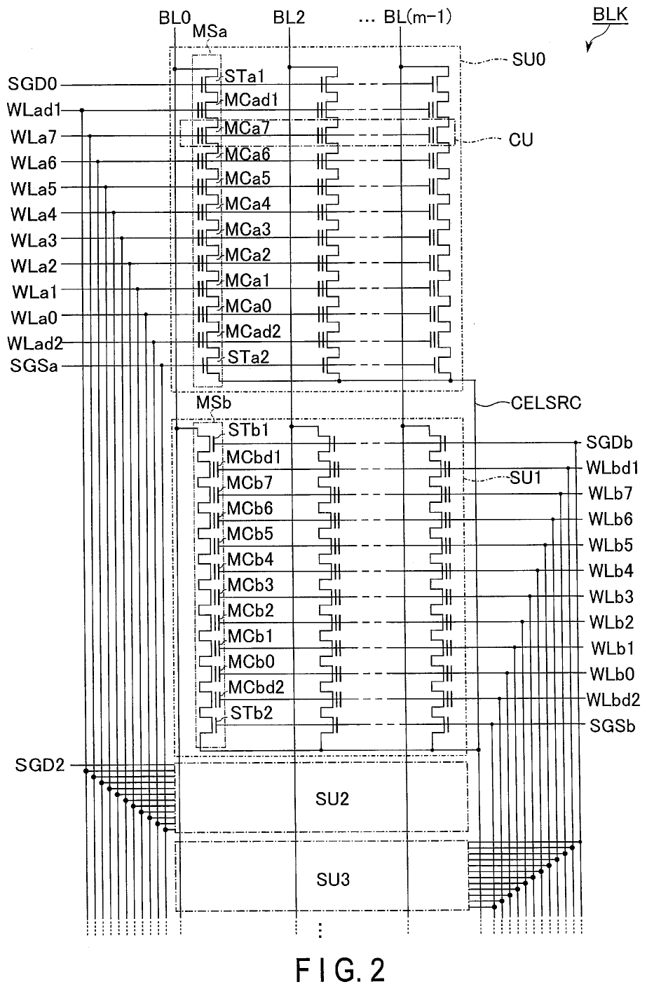

Next, the structure of the memory cell array 10 according to the first embodiment will be explained with reference to FIG. 2, which is an equivalent circuit diagram of a block BLK.

As illustrated in FIG. 2, a block BLK may include eight string units SU (SU0, SU1, SU2, SU3, . . . SU7). Of the eight string units SU0 to SU7, four string units (SU0 to SU3) are shown in the example of FIG. 2. In the following description, the string units SU0, SU2, SU4, and SU6 may be collectively referred to as “string units SUa”, and the string units SU1, SU3, SU5, and SU7 may be collectively referred to as “string units Sub”.

Each of the string units SU includes a plurality of memory strings MS. In the following, when the memory strings MS in a string unit SUa and the memory strings MS in a string unit SUb need to be mutually distinguished, they will be referred to as “memory strings MSa” and “memory strings MSb”, respectively. For other structural components and interconnects, “a” will be attached to those corresponding to a string unit SUa, and “b” will be attached to those corresponding to a string unit SUb, as needed, so as to be mutually distinguishable.

A memory string MS may include eight memory cell transistors MC (MC0 to MC7), two dummy cell transistors MCd1 and MCd2, and selection transistors ST1 and ST2. A memory cell transistor MC includes a control gate and a charge storage film, and stores data in a nonvolatile manner. The eight memory cell transistors MC and two dummy cell transistors MCd are coupled in series between the source of the selection transistor ST1 and the drain of the selection transistor ST2. In particular, the dummy cell transistor MCd1 is coupled in series between the selection transistor ST1 and the memory cell transistor MC7, and the dummy cell transistor MCd2 is coupled in series between the selection transistor ST2 and the memory cell transistor MC0.

The gates of the selection transistors STa1 in the string units SUa are coupled to the corresponding select gate lines SGDa. On the other hand, the gates of the selection transistors STb1 in the string units SUb are commonly coupled to the select gate line SGDb. The five select gate lines SGD0, SGD2, SGD4, SGD6, and SGDb are independently controlled by the driver module 14.

The gates of the selection transistors STa2 of the string units SUa in the same block BLK may be commonly coupled to the select gate line SGSa. The gates of the selection transistor STb2 of the string unit SUb in the same block block BLK may be commonly coupled to the select gate line SGSb. The select gate lines SGSa and SGSb may be either commonly coupled or independently controllable.

The control gates of the memory cell transistors MCa (MCa0 to MCa7) and dummy cell transistors MCad (MCad1 and MCad2) in the string units SUa of the same block BLK are commonly coupled to the word lines WLa (WLa0 to WLa7) and dummy word lines WLad (WLad1 and WLad2), respectively. The control gates of the memory cell transistors MCb (MCb0 to MCb7) and dummy cell transistors MCbd (MCbd1 and MCbd2) in the string units Sub are commonly coupled to the word lines WLb (WLb0 to WLb7) and dummy word lines WLbd (WLbd1 and WLbd2), respectively. The word lines WLa and WLb, and dummy word lines WLad and WLbd are independently controlled by the driver module 14.

A block BLK may serve as a data erase unit. That is, the data stored in the memory cell transistors MC in the same block BLK is collectively erased.

Furthermore, the bit lines BL (BL0 to BL(m−1) are respectively coupled to the drains of the selection transistors ST1 in the memory strings MS belonged to the corresponding columns of the memory cell array 10, where m is a natural number). That is, a common bit line BL is coupled to a memory string MSa in each of the string units SUa and to a memory string MSb in each of the string units SUb. The sources of the selection transistors ST2 are commonly coupled to a source line CELSRC.

That is, a string unit SU is a set including memory strings MS, each being coupled to a different bit line BL and to the same select gate line SGD. In a string unit SU, a set including memory cell transistors MC coupled to the same word line WL may be referred to as a “cell unit CU”. A block BLK is a set including string units SUa that share the same word lines WLa0 to WLa7 and string units SUb that share the same word lines WLb0 to WLb7. A memory cell array 10 is a set including blocks BLK that share multiple bit lines BL.

In the memory cell array 10, the select gate line SGS, dummy word line WLd2, word lines WL0 to WL7, dummy word line WLd1, and select gate line SGD are sequentially stacked above the semiconductor substrate. As a result, a selection transistor ST2, a dummy cell transistor MCd1, memory cell transistor MC0 to MC7, a dummy cell transistor MCd2, and a selection transistor ST1 are three-dimensionally stacked in this order.

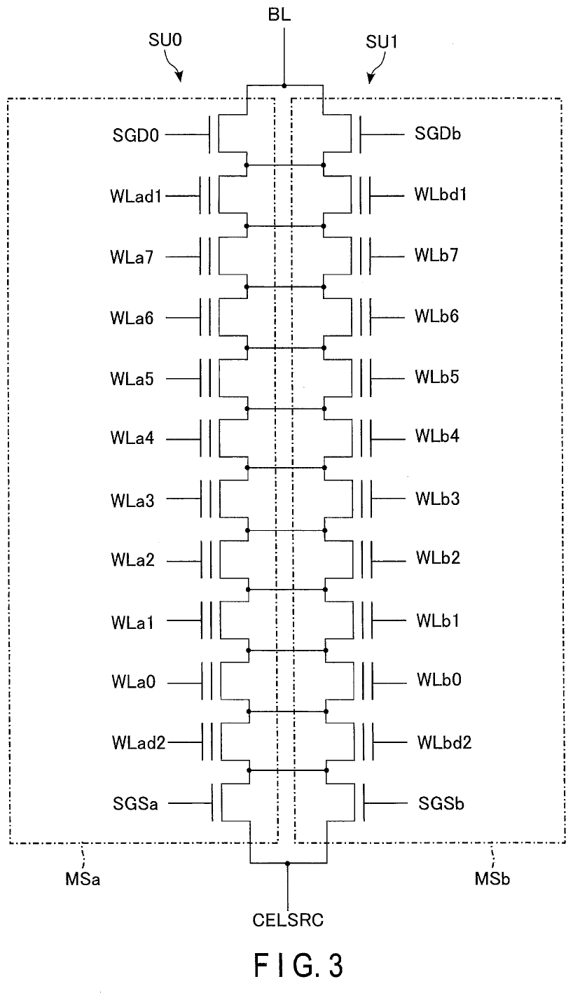

A memory string MSa and a memory string MSb that are coupled in parallel to a common bit line may form one set. The circuit structure of a set including memory strings MSa and MSb will be explained by referring to the circuit diagram of FIG. 3. An exemplary set including a memory string MSa in a string unit SU0 and a memory string MSb in a string unit SU1 is illustrated in FIG. 3.

As illustrated in FIG. 3, in a set including a memory string MSa and a memory string MSb, current paths may be shared. In particular, a current path between the selection transistor STa1 and dummy cell transistor MCad1 is electrically coupled to a current path between the selection transistor STb1 and dummy cell transistor MCbd1. A current path between the dummy cell transistor MCad1 and memory cell transistor MCa7 is electrically coupled to a current path between the dummy cell transistor MCbd1 and memory cell transistor MCb7. A current path between the adjacent memory cell transistors MCak and MCa(k+1) is electrically coupled to a current path of the adjacent memory cell transistors MCbk and MCb(k+1) (0≤k≤7). A current path between the memory cell transistor MCa0 and dummy cell transistor MCad2 is electrically coupled to a current path between the memory cell transistor MCb0 and dummy cell transistor MCbd2. A current path between the dummy cell transistor MCad2 and selection transistor STa2 is electrically coupled to a current path between the dummy cell transistor MCbd2 and selection transistor STb2.

### 1.1.3 Layout of Memory Cell Array

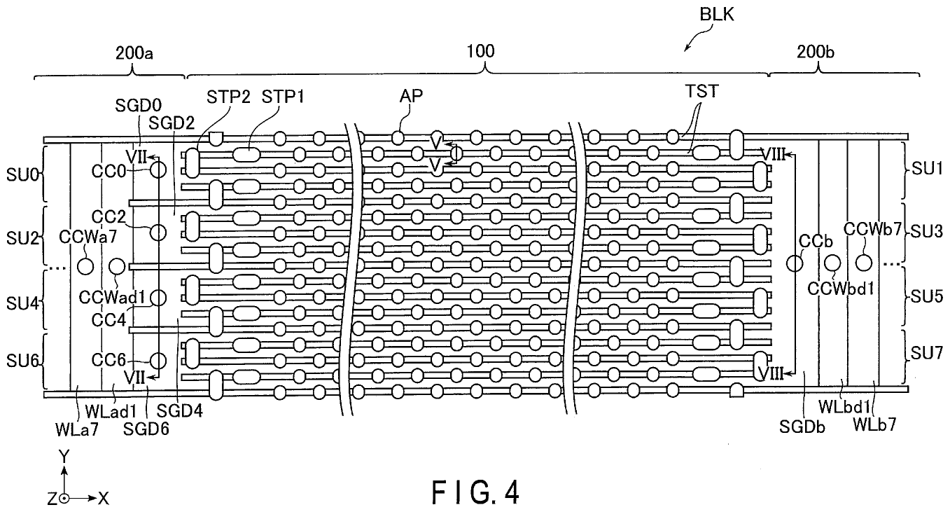

Next, the layout of a memory cell array according to the first embodiment will be explained with reference to FIG. 4.

FIG. 4 shows an exemplary planar layout of an area corresponding to one block in the memory cell array of the memory device according to the first embodiment. For the sake of simplicity, structural components such as interlayer insulating films and interconnects are omitted from FIG. 4. In FIG. 4 and subsequent drawings, the two directions parallel to the surface of the semiconductor substrate and orthogonal to each other are defined as “X direction” and “Y direction”, and a direction orthogonal to the surface (X-Y plane) containing the X direction and Y direction is defined as “Z direction” (layer stacking direction).

As illustrated in FIG. 4, the memory cell array 10 includes a cell region 100 and hookup regions 200 (200a and 200b). The hookup regions 200a and 200b are arranged, in the X direction, at the two ends of the cell region 100 in such a manner as to sandwich the cell region 100 in the X direction. That is, the hookup region 200a is arranged at one end of the cell region 100 in the X direction, and the hookup region 200b is arranged at the other end of the cell region 100 in the X direction.

A layer for providing the select gate lines SGSa and SGSb, a layer for providing the dummy word lines WLad2 and WLbd2, a layer for providing the word lines WLa0 and WLb0, a layer for providing the word lines WLa1 and WLb1, . . . , a layer for providing the word lines WLa7 and WLb7, a layer for providing the dummy word lines WLad1 and WLbd1, and a layer for providing the select gate lines SGD0, SGD2, SGD4, SGD6, and SGDb, are stacked along the Z direction across the cell region 100 and hookup region 200.

For instance, the select gate lines SGSa and SGSb are provided in the same layer, and the dummy word lines WLad2 and WLbd2 are provided in the same layer. The word lines WLai and WLbi (0≤i≤7) are provided in the same layer. The dummy word lines WLad1 and WLbd1 are provided in the same layer, and the select gate lines SGD0, SGD2, SGD4, SGD6, and SGDb are provided in the same layer.

The word lines WLa0 and WLb0 are provided above the select gate lines SGSa and SGSb, and the word lines WLaj and WLbj (1≤j≤7) are provided above the word lines WLa(j−1) and WLb(j−1). The select gate lines SGD0, SGD2, SGD4, and SGD6 are provided above the word line WLa7, and the select gate line SGDb is provided above the word line WLb7. In the following description, the select gate lines SGD and SGS, dummy word lines WLd, and word lines WL may be collectively referred to as “stacked interconnects”.

First, the cell region 100 will be explained. In the cell region 100, a plurality of trench structures TST, a plurality of memory pillars AP that include the structural components of memory cells, a plurality of pillars STP1 used for replacement process of the stacked interconnects, and a plurality of pillars STP2 used for separation process of the stacked interconnects are provided in such a manner as to penetrate all the stacked interconnects. For instance, the memory pillars AP are provided in the center portion of the cell region 100, the pillars STP1 are provided in the end portions of the cell region 100 with respect to the memory pillars AP, and the pillars STP2 are provided in the end portions on the outer side with respect to the pillars STP1 along the X direction.

The trench structures TST extend in the X direction and are aligned in the Y direction. The trench structures TST are separated from each other by the memory pillars AP aligned at predetermined intervals in the X direction. The memory pillars AP are arranged in a staggered manner on the trench structures TST. That is, the memory pillars AP arranged to partition one of two trench structures TST adjacent in the Y direction are displaced half a pitch in the X direction with respect to the memory pillars AP, which are arranged to partition the other one of the two trench structures TST.

A pillar STP1 is provided at each of the two ends of every other one of the trench structures TST aligned in the Y direction in such a manner as to partition the trench structure TST. As such, every other one of the trench structures TST aligned in the Y direction has three portions separated by the two pillars STP1, i.e., the center portion in which a plurality of memory pillars AP are arranged, and two end portions in which no memory pillar AP is arranged. In the example of FIG. 4, any two trench structures TST adjacent to the trench structure TST that is separated by the pillars STP1 are illustrated as including no pillar STP1. Pillars STP1, however, may be arranged in the end portions of the two trench structures TST.

Of the stacked interconnects, the portion interposed between any one of the trench structures TST aligned in the Y direction and one of the two trench structures TST adjacent to this trench structure TST is separated by a pillar STP2 in one of the two end portions of the cell region 100 (e.g., on the hookup region 200a side). The portion interposed between the trench structure TST and the other one of the adjacent trench structures TST in the stacked interconnects is separated by a pillar STP2 in the other one of the two end portions of the cell region 100 (e.g., on the hookup region 200b side).

With the above structure, the stacked interconnects are separated in the cell region 100 into a comb-shaped portion extending from the hookup region 200a side (select gate line SGSa, dummy word line WLad2, word lines WLa0 to WLa7, dummy word line WLad1, and select gate line SGDa), and a comb-shaped portion extending from the hookup region 200b side (select gate line SGSb, dummy word line WLbd2, word lines WLb0 to WLb7, dummy word line WLbd1, and select gate line SGDb). The opposing two side surfaces of each tooth of the comb-shaped stacked interconnects extending in the X direction are in contact with a plurality of memory pillars AP.

Next, the hookup regions 200 will be explained.

In a hookup region 200, the stacked interconnects may be formed into a staircase pattern in the X direction. That is, the lower the layer, the further the wirings of the stacked interconnects extend in the X direction so that each of the wirings in the stacked interconnects has a terrace region above which no other stacked interconnect wirings are arranged.

In the hookup region 200a, the wiring corresponding to the select gate line SGDa may be separated into four portions by three trench structures TST. The separated four portions correspond to select gate lines SGD0, SGD2, SGD4, and SGD6. Contacts CC0, CC2, CC4, and CC6 are respectively provided on the terrace regions of these four portions.

For the dummy word line WLad1, a contact CCWad1 is provided on the corresponding terrace region.

For the word lines WLa0 to WLa7 (part of which is not shown), contacts CPWa0 to CPWa7 (part of which is not shown) are provided on the corresponding terrace regions.

For the dummy word line WLad2 and select gate line SGSa, contacts (not shown) are provided on the corresponding terrace regions (not shown).

In the hookup region 200b, the wiring corresponding to the select gate line SGDb is not separated, for example by a trench structure TST. That is, the wiring corresponding to the select gate line SGDb is shared by the string units SU1, SU3, SU5, and SU7. A contact CCb is provided on the terrace region corresponding to the select gate line SGDb.

For the dummy word line WLbd1, a contact CCWbd1 is provided on the corresponding terrace region.

For the word lines WLb0 to WLb7 (part of which is not shown), contacts CPWb0 to CPWb7 (part of which is not shown) are provided on the corresponding terrace regions.

For the dummy word line WLbd2 and select gate line SGSb, contacts (not shown) are provided on the corresponding terrace regions (not shown).

With the above structure, all of the stacked interconnects can be upwardly hooked up from the hookup regions 200 with respect to the memory cell array 10.

FIG. 4 shows only one of the blocks BLK of the memory cell array 10, omitting other blocks BLK. In actuality, however, blocks BLK0 to BLKn having a structure equivalent to FIG. 4 are aligned in this order in the Y direction.

### 1.1.4 Memory Pillars

An example of a memory pillar in the memory device according to the first embodiment will be explained below.

### 1.1.4.1 Structure of Vertical Cross Section

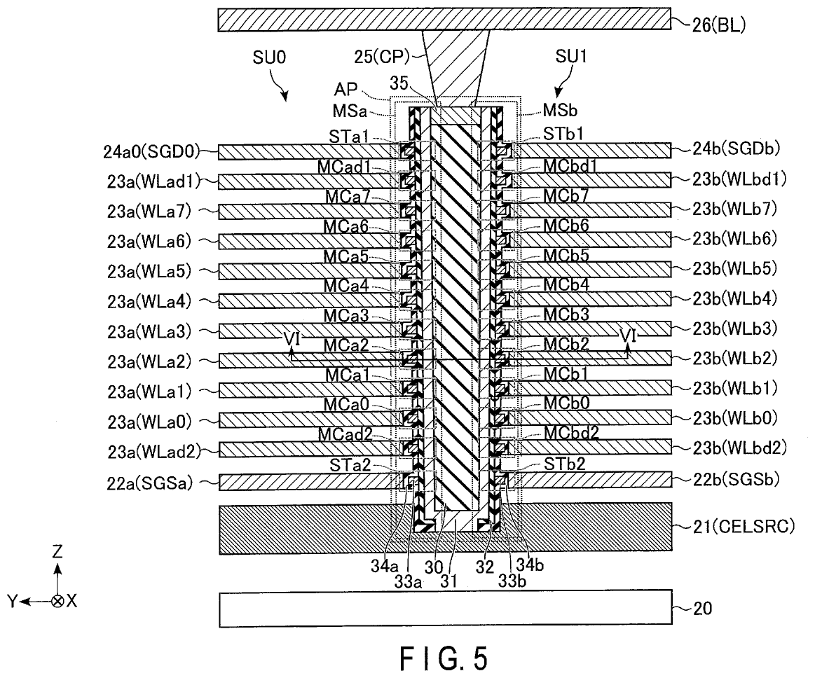

First, the structure of a memory pillar in the vertical cross section of the memory device according to the first embodiment will be explained with reference to FIG. 5.

FIG. 5 is a cross-sectional view of the structure of FIG. 4, taken along line V-V. For the sake of simplicity, structural components such as interlayer insulating films are omitted from FIG. 5.

First, by referring to FIG. 5, the structure of a memory pillar AP taken along the Y-Z plane will be described. FIG. 5 illustrates a structure including a memory pillar AP corresponding to a set including a memory string MSa in the string unit SU0 and a memory string MSb in the string unit SU1, and a plurality of conductors that serve as interconnects coupled to this memory pillar AP.

As illustrated in FIG. 5, a conductor 21 that serves as a source line CELSRC is provided above the semiconductor substrate 20. The conductor 21 is formed of a conductive material, for which an impurity-doped n-type semiconductor or a metallic material may be adopted. The conductor 21 may be a stacked structure including a layer of semiconductor and a layer of metal. Circuits such as a driver module 14, a row decoder module 15, and a sense amplifier module 16 may be provided between the semiconductor substrate 20 and conductor 21.

A conductor 22a and a conductor 22b are stacked in the Z direction above the conductor 21 with an unillustrated insulator interposed, and are provided on the same layer so as to serve as a select gate line SGSa and a select gate line SGSb, respectively. Above the conductor 22a, ten layers of the conductors 23a are stacked in the Z direction, with an unillustrated insulator interposed between any adjacent layers among the ten, to serve as a dummy word line WLad2, word lines WLa0 to WLa7, and a dummy word line WLad1. Similarly, ten layers of conductors 23b are stacked above the conductor 22b in the Z direction, with an unillustrated insulator interposed between the adjacent ones, to serve as a dummy word line WLbd2, word lines WLb0 to WLb7, and a dummy word line WLbd1. Above the conductors 23a and 23b, a conductor 24a0 and a portion of a conductor 24b corresponding to the string unit SU1 are respectively stacked in the Z direction with an unillustrated insulator interposed between the adjacent layers. The conductor 24a0 and conductor 24b serve as a select gate line SGD0 and a select gate line SGDb, respectively.

The conductors 22a to 24a0 and 22b to 24b are formed of a conductive material, for which an impurity-doped n-type semiconductor or p-type semiconductor, or metallic material may be adopted. For instance, the conductors 22a to 24a0 and 22b to 24b may have a structure of tungsten (W) coated with titanium nitride (TiN). A titanium nitride layer is capable of serving as a barrier layer preventing tungsten and silicon oxide (SiO₂) from reacting with each other or as a layer that improves the adhesion of tungsten when forming a tungsten layer through chemical vapor deposition (CVD). The conductors 22a to 24a0 and 22b to 24b may be such that the aforementioned conductive material is further coated with aluminum oxide (AlO).

A conductor 26 may be provided above the conductors 24a0 and 24b with an insulator (not shown) interposed. Conductors 26 extend in the Y direction and are aligned in the X direction in a linear pattern, each used as a bit line BL. The conductors 26 may include copper (Cu).

The memory pillar AP is arranged between the conductors 22a to 24a0 and conductors 22b to 24b to extend in the Z direction, with the bottom surface in contact with the conductor 21. The conductors 22a to 24a0 and the conductors 22b to 24b are electrically separated by the memory pillar AP, the trench structures TST separated by the memory pillar AP, and the pillars STP1 and STP2.

A memory pillar AP includes a core member 30, a semiconductor 31, tunnel insulating film 32, a plurality of charge storage films 33 (a plurality of charge storage films 33a and a plurality of charge storage films 33b), block insulating films 34 (34a and 34b), and a semiconductor 35. The charge storage film 33a is provided for each of the layers of the conductors 22a to 24a0. The charge storage film 33b is provided for each of the layers of the conductors 22b to 24b.

The core member 30 extends in the Z direction, with its upper end included in a layer above the conductors 24a0 and 24b, and its lower end included in a layer below the conductors 22a and 22b. The core member 30 may contain silicon oxide.

The semiconductor 31 covers the bottom surface and side surface of the core member 30. The upper end of the semiconductor 31 is above the upper end of the core member 30 and may be approximately at the same level as the upper end of the semiconductor 35. The lower end of the semiconductor 31 is below the lower end of the core member 30 and is in contact with the conductor 21. The semiconductor 31 may contain polysilicon.

The tunnel insulating film 32 covers the side surface of the semiconductor 31. The upper end of the tunnel insulating film 32 is approximately at the same level as the upper end of the semiconductor 31 and may contain silicon oxide.

In each layer of the conductors 22a to 24a0, a charge storage film 33a is provided on one of side surfaces of the tunnel insulating film 32 extending along the X-Z plane. The block insulating film 34a is formed as a continuous film that covers a plurality of charge storage films 33a. Each of the conductors 22a to 24a0 is in contact with the block insulating film 34a at a corresponding layer.

In each layer of the conductors 22b to 24b, the charge storage film 33b is provided on the other side of the side surfaces of the tunnel insulating film 32 extending along the X-Z plane. The block insulating film 34b is provided as a continuous film that covers a plurality of charge storage films 33b. Each of the conductors 22b to 24b is in contact with the block insulating film 34b at a corresponding layer.

The charge storage films 33a and 33b may contain polysilicon. The block insulating films 34a and 34b may contain silicon oxide (SiO₂). An unillustrated block insulating film may also be provided between the charge storage films 33a and block insulating film 34a, and between the charge storage films 33b and block insulating film 34b. Such a block insulating film may be formed of a material of a dielectric constant (High-k) higher than that of the block insulating films 34a and 34b, and may contain hafnium silicate (HfSiO) or zirconium silicate (ZrSiO).

The semiconductor 35 may contain polysilicon, and is in contact with the top surface of the core member 30 and the side surface of a portion of the semiconductor 31 above the core member 30.

A conductor 25 is provided on the top surface of the semiconductor 35 to serve as a pillar-shaped contact CP. One conductor 26 is in contact with, and electrically coupled to, the top surface of the corresponding one of the conductors 25. As such, the semiconductor 31 can form two parallel current paths aligned along the Y axis between the conductor 26 and conductor 21 through the core member 30.

In the above-described memory pillar AP, the portion intersecting with the conductor 22a serves as a selection transistor STa2, and the portion intersecting with the conductor 22b serves as a selection transistor STb2. The portions intersecting with the conductors 23a serve as dummy cell transistors MCad and memory cell transistors MCa, and the portions intersecting with the conductors 23b serve as dummy cell transistors MCbd and memory cell transistors MCb. The portion intersecting with the conductor 24a0 serves as a selection transistor STa1, and the portion intersecting with the conductor 24b serves as a selection transistor STb1.

In other words, the semiconductor 31 is used as a channel for each of the selection transistors STa1 and STb1, dummy cell transistors MCad and MCbd, memory cell transistors MCa and MCb, and selection transistors STa2 and STb2. The charge storage films 33a are used as the floating gates of the memory cell transistors MCa, dummy cell transistors MCad, and selection transistors STa1 and STa2. The charge storage films 33b are used as the floating gates of the memory cell transistors MCb, dummy cell transistors MCbd, and selection transistor STb1 and STb2. As such, the memory pillar AP serves as a set including two memory strings MSa and MSb.

The above structure of the memory pillar AP has been described merely as an example; a memory pillar AP may have indeed a different structure. For instance, the number of conductors 23 may be determined based on the numbers, which can be freely designed, of word lines WL and dummy word lines WLd. Conductors 22 and 24, the numbers of which can be freely determined, may be assigned to the select gate lines SGS and SGD. When plural layers of conductors 22 are assigned to a select gate line SGS, different types of conductors may be adopted for the layers of the conductors 22. The electrical coupling between the semiconductor 35 and conductor 26 may be established via two or more contacts, or via any other interconnect.

### 1.1.4.2 Structure of Traverse Cross Section

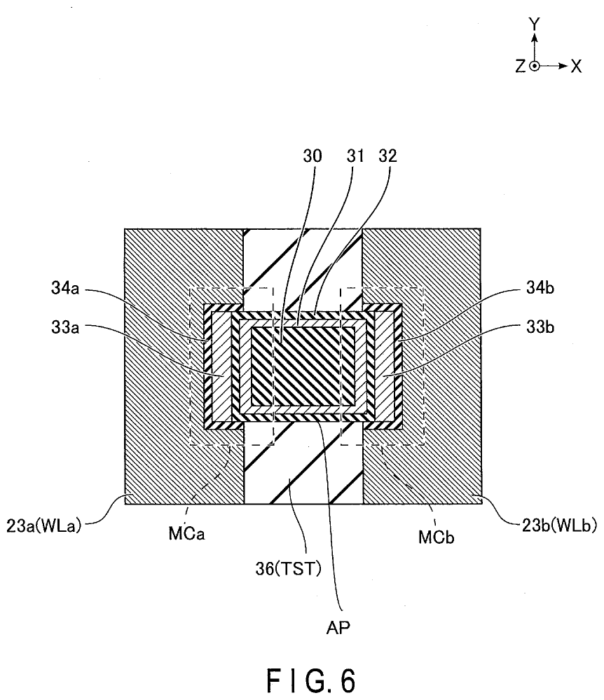

Next, the structure of a memory pillar in the traverse cross section of the memory device according to the first embodiment will be explained with reference to FIG. 6.

FIG. 6 is a cross-sectional view of FIG. 5 taken along line VI-VI, showing word lines WLa and WLb, and a memory pillar AP and a trench structure TST that are formed between the word lines WLa and WLb and.

In FIG. 6, the semiconductor 31 covers the core member 30 on the X-Y plane. That is, in the semiconductor 31, the portion that sandwiches the tunnel insulating film 32 in between with the charge storage film 33a is coupled to the portion that sandwiches the tunnel insulating film 32 in between with the charge storage film 33b, by the portions extending in the X direction. With such a structure, the channels of the memory cell transistors MCa and MCb in the same layer are electrically coupled to each other by the semiconductor 31 formed as a continuous film.

Thus, a set of memory strings MSa and MSb in a memory pillar AP forms a circuit structure as explained with reference to FIG. 3.

### 1.1.5 Select Gate Lines SGD in Hookup Region

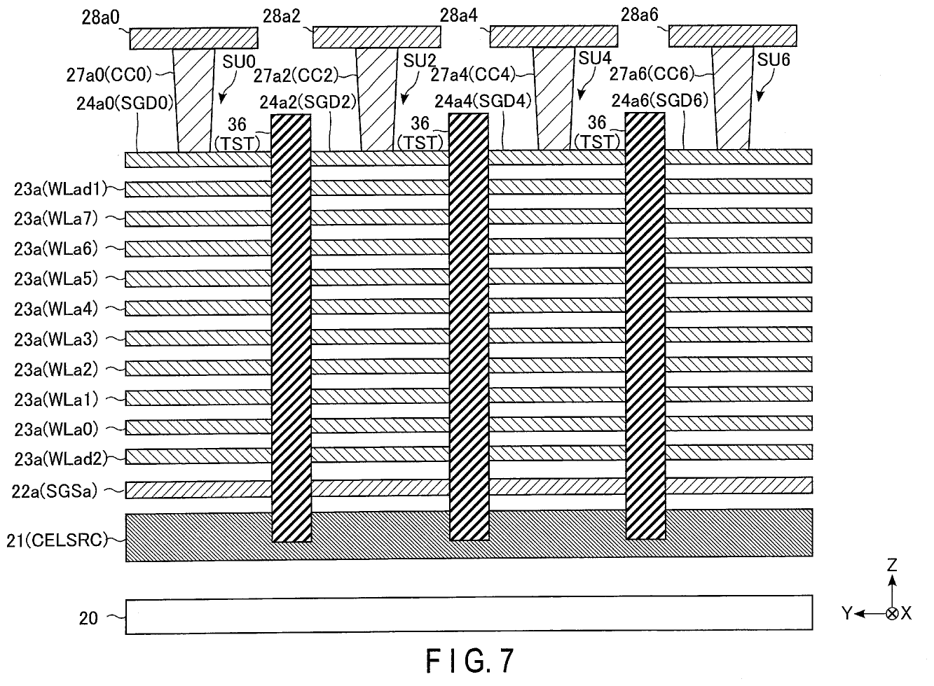

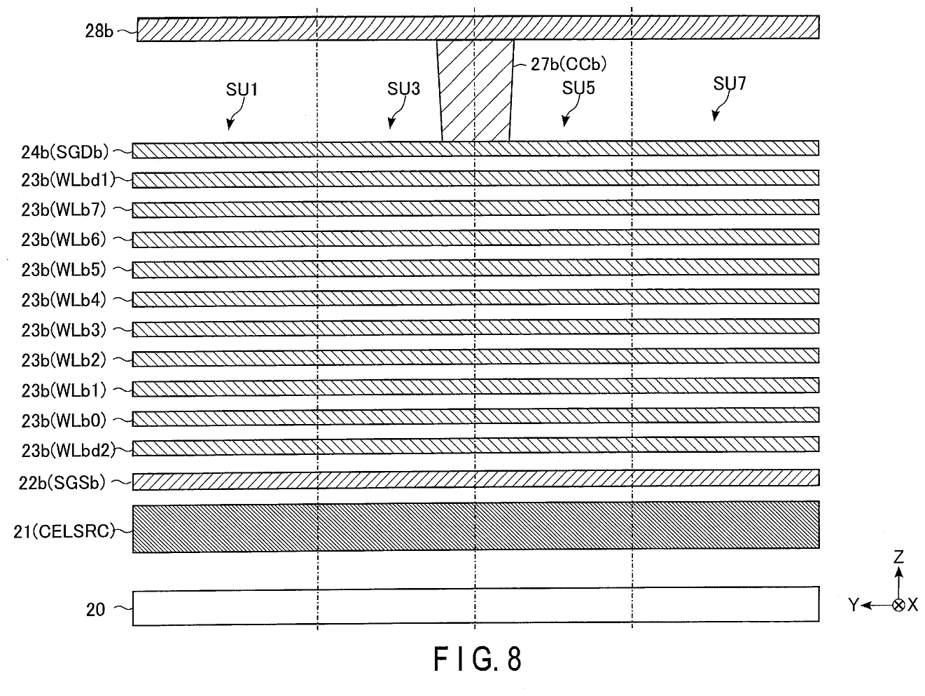

Next, the structure of select gate lines SGD in a hookup region will be explained with reference to FIGS. 7 and 8.

FIG. 7 is a cross-sectional view of the hookup region 200a in the memory cell array 10 taken along line VII-VII of FIG. 4. FIG. 8 is a cross-sectional view of the hookup region 200b in the memory cell array 10 taken along line VIII-VIII of FIG. 4. That is, FIG. 7 shows a cross section including contacts CC0, CC2, CC4, and CC6 in the hookup region 200a. FIG. 8 shows a contact CCb in the hookup region 200b.

First, the structure of the select gate lines SGDa in the hookup region 200a will be explained with reference to FIG. 7.

As illustrated in FIG. 7, the conductor 24a is separated into conductors 24a0, 24a2, 24a4, and 24a6 by three insulators 36, each of which serves as a trench structure TST. The conductors 24a0, 24a2, 24a4, and 24a6 serve as select gate lines SGD0, SGD2, SGD4, and SGD6, respectively.

On the top surfaces of the conductors 24a0, 24a2, 24a4, and 24a6, conductors 27a0, 27a2, 27a4, and 27a6 are arranged to serve as contacts CC0, CC2, CC4, and CC6, respectively. On the top surfaces of the conductors 27a0, 27a2, 27a4, and 27a6, conductors 28a0, 28a2, 28a4, and 28a6 are arranged, respectively. The conductors 28a0, 28a2, 28a4, and 28a6 are electrically coupled respectively to four SGD drivers (not shown) in the driver module 14 in such a manner as to independently drive the select gate lines SGD0, SGD2, SGD4, and SGD6.

Next, the structure of the select gate line SGDb in the hookup region 200b will be explained with reference to FIG. 8.

As illustrated in FIG. 8, a conductor 27b is arranged on the top surface of the conductor 24b to serve as a contact CCb. In the example of FIG. 8, a single conductor 27b is illustrated as being formed across the boundary of the string units SU3 and SU5. This is not a limitation, however, and any number of conductors 27b may be formed at any position on the conductor 24b.

A conductor 28b is arranged on the top surface of the conductor 27b. The conductor 28b is electrically coupled to an SGD driver (not shown) in the driver module 14 in such a manner as to drive the select gate line SGDb.

With the above structure, the five select gate lines SGD0, SGD2, SGD4, SGD6, and SGDb are electrically coupled to the corresponding SGD drivers.

### 1.2 Operation of Memory Device

The operation of the memory device according to the first embodiment will be explained.

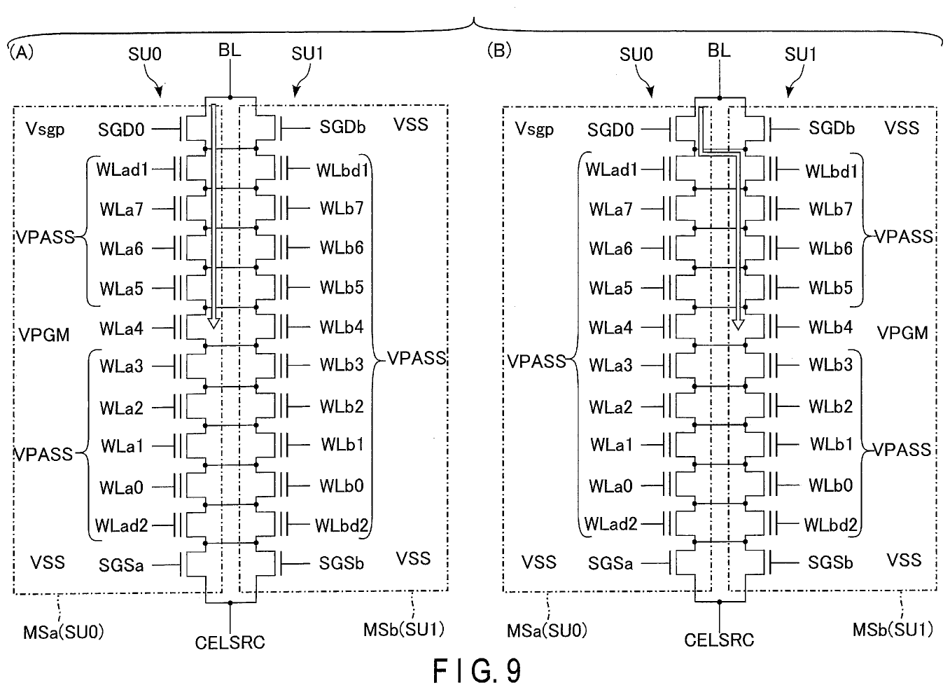

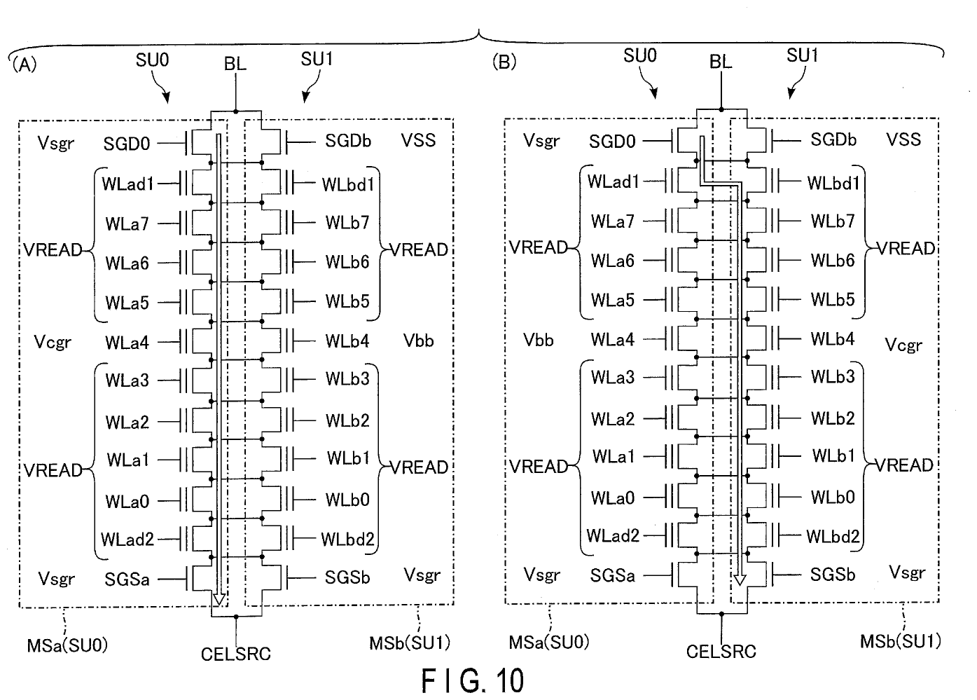

FIG. 9 and 10 are schematic diagrams explaining the application of voltages to the stacked interconnects coupled to a set including the memory string MSa in the string unit SU0 and the memory string MSb in the string unit an during a write operation and read operation, respectively. In FIG. 9(A), the memory cell transistor MCa4 in the memory string MSa is selected as a target of a write operation, while in FIG. 9(B), the memory cell transistor MCb4 in the memory string MSb is selected as a target of a write operation. In FIG. 10(A), the memory cell transistor MCa4 in the memory string MSa is selected as a target of a read operation, while in FIG. 10(B), the memory cell transistor MCb4 in the memory string MSb is selected as a target of a read operation.

The voltages applied during a write operation will be explained first, with reference to FIG. 9.

FIG. 9(A) shows voltages applied when data is to be written into the memory cell transistor MCa4 of the memory string MSa. As illustrated in FIG. 9(A), the row decoder module 15 applies a voltage VPGM to the selected word line WLa4, and a voltage VPASS to other word lines WLa0 to WLa3, WLa5 to WLa7, WLb0 to WLb7 that are not selected and dummy word lines WLad1, WLad2, WLbd1, and WLbd2. The voltage VPASS is a voltage that turns the memory cell transistor MC on regardless of the data it stores. The voltage VPGM is a voltage that is higher than the voltage VPASS and capable of raising the threshold voltage by injecting charges into the charge storage film 33a or 33b.

The row decoder module 15 applies a voltage Vsgp to the select gate line SGD0, and a voltage VSS to the select gate lines SGDb, SGSa and SGSb. The voltage VSS is a voltage that turns off the selection transistors ST1 and ST2, and dummy cell transistors MCd. The voltage Vsgp is a voltage that may be applied to the selection transistors ST1 and ST2 during a write operation to turn the selection transistors ST1 and ST2 on.

In the above manner, a path for supplying charge via the selection transistor STa1, dummy cell transistor MCad1, and memory cell transistors MCa7 to MCa5 to raise the threshold voltage of the memory cell transistor MCa4 is formed in the memory string MSa.

FIG. 9(B) shows voltages applied when data is to be written into the memory cell transistor MCb4 of the memory string MSb. The row decoder module 15 applies a voltage VPGM to the selected word line WLb4, and a voltage VPASS to other word lines WLb0 to WLb3, WLb5 to WLb7, and WLa0 to WLa7 that are not selected and dummy word lines WLad1, WLad2, WLbd1, and WLbd2, as illustrated in FIG. 9(B).

The row decoder module 15 applies a voltage Vsgp to the select gate line SGD0, and a voltage VSS to the select gate lines SGDb, SGSa and SGSb.

In the above manner, a path for supplying charge via the selection transistor STa1, dummy cell transistor MCbd1, and memory cell transistors MCb7 to MCb5 to raise the threshold voltage of the memory cell transistor MCb4 is formed in the memory strings MSa and MSb.

As described above, the row decoder module 15 turns the selection transistor STa1 on and the selection transistor STb1 off, based on whichever of the string units SU0 and SU1 is a write target. In this manner, the row decoder module 15 can supply to the write target memory cell transistor MC, by the path via the selection transistor Sta1, the charge for raising its threshold voltage.

The voltages applied during a read operation will be explained with reference to FIG. 10.

FIG. 10(A) shows voltages applied when data is to be read from the memory cell transistor MCa4 of the memory string MSa. As illustrated in FIG. 10(A), the row decoder module 15 applies a voltage Vcgr to the selected word line WLa4, and a voltage VREAD to other word lines WLa0 to WLa3, WLa5 to WLa7, WLb0 to WLb7 that are not selected, and dummy word lines WLad1, WLad2, WLbd, and WLbd2. The voltage VREAD is a voltage that turns the memory cell transistor MC on regardless of the data it stores. The voltage Vcgr is lower than a voltage VREAD, and is to determine in which voltage range the threshold voltage of the memory cell transistor MC falls. For instance, a read current flows into a read target memory cell transistor MC when a threshold voltage of the read target memory cell transistor MC is lower than the voltage Vcgr, but does not flow when the threshold voltage is higher than the voltage Vcgr.

The row decoder module 15 further applies a voltage Vsgr to the select gate line SGD0, and a voltage VSS to the select gate lines SGDb, SGSa and SGSb. The voltage Vsgr is a voltage applied to the selection transistors ST1 and ST2 during a read operation to turn the selection transistors ST1 and ST2 on.

In the above manner, a current path for passing a read current to the memory cell transistor MCa4 via the selection transistor STa1, dummy cell transistor MCad1, and memory cell transistors MCa7 to MCa5 is formed in the memory string MSa.

FIG. 10(B) shows voltages applied when data is to be read from the memory cell transistor MCb4 of the memory string MSb. The row decoder module 15 applies a voltage Vcgr to the selected word line WLb4, and a voltage VREAD to other word lines WLb0 to WLb3, WLb5 to WLb7, and WLa0 to WLa7 that are not selected, and dummy word lines WLad1, WLad2, WLbd1, and WLbd2, as illustrated in FIG. 10(B).

The row decoder module 15 further applies a voltage Vsgr to the select gate line SGD0, and a voltage VSS to the select gate lines SGDb, SGSa and SGSb.

In the above manner, a current path for passing a read current to the memory cell transistor MCb4 via the selection transistor STa1, dummy cell transistor MCbd1, and memory cell transistors MCb7 to MCb5 is formed in the memory strings MSa and MSb.

As described above, the row decoder module 15 turns the selection transistor STa1 on and the selection transistor STb1 off based on whichever of the string units SU0 and SU1 is a read target. As described above, whichever of the string units SU0 and SU1 is a read target, the row decoder module 15 forms a current path for passing a read current to the read target memory cell transistor MC via the selection transistor STa1.

### 1.3 Manufacturing Method of Memory Device

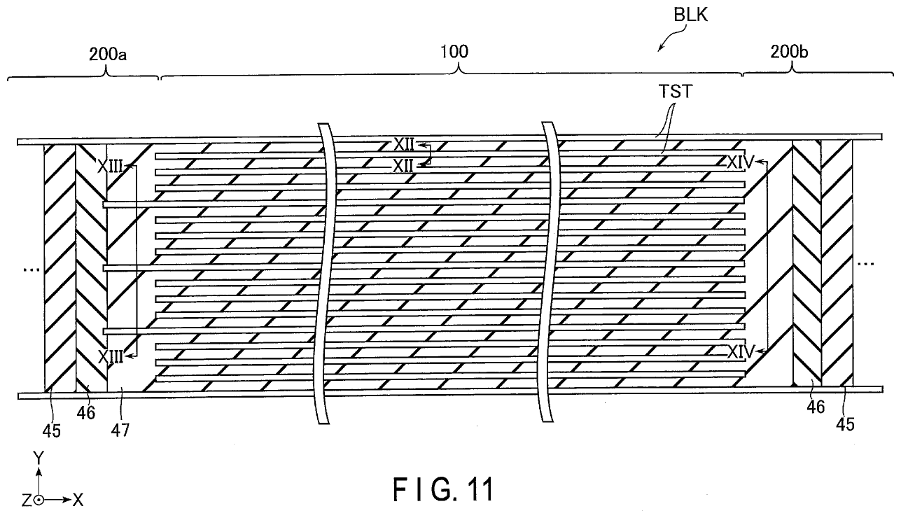

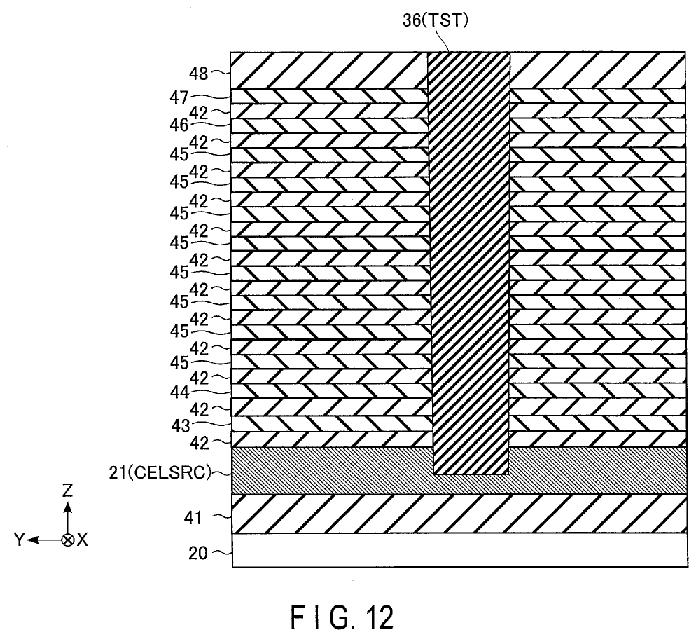

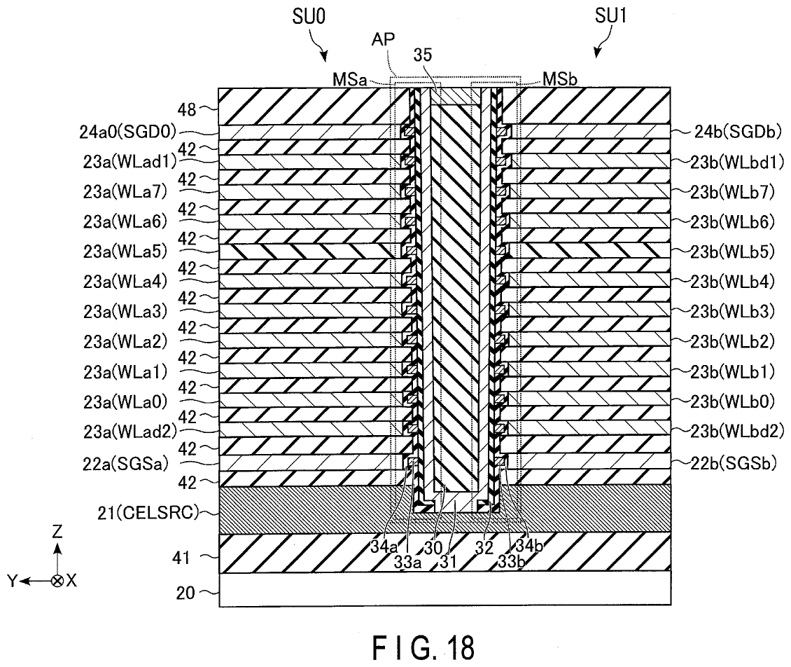

An exemplary manufacturing process of a memory cell array in the memory device according to the first embodiment will be described below. FIGS. 11, 15, 17, and 19 show exemplary planar layouts of a memory cell array viewed from above in the manufacturing process of a memory device according to the first embodiment. FIGS. 12, 13, 14, 16, 18, 20, and 21 show exemplary cross-sectional partial structures of the memory cell array corresponding to the planar layouts of the above manufacturing process. The planar layout in each manufacturing process corresponds to FIG. 4, and structural components such as interlayer insulating films and interconnects are omitted as needed.

First, as illustrated in FIG. 11, a layer stack is formed in which sacrificial members corresponding to the select gate line SGS, word lines WL0 to WL7, and select gate line SGD are stacked. In the layer stack, the stacked sacrificial members are formed in a staircase pattern such that each of the stacked sacrificial members has a terrace region at the two end portions (portions corresponding to the hookup regions 200a and 200b) in the X direction. Thereafter, the trench structures TST are formed in the layer stack to extend in the X direction and to be aligned in the Y direction.

FIG. 12 is a cross-sectional view of a cell region 100 in the memory cell array 10 taken along line XII-XII in FIG. 11. First, an insulator 41 and a conductor 21 are sequentially stacked on the semiconductor substrate 20 as illustrated in FIG. 12. An insulator 42, a sacrificial member 43, an insulator 42, and a sacrificial member 44 are sequentially stacked on the conductor 21. Insulators 42 and sacrificial members 45 are alternately stacked on the sacrificial member 44 multiple times (eight times in the example of FIG. 12). Insulator 42, sacrificial member 46, insulator 42, and sacrificial member 47 are sequentially stacked on the sacrificial member 45. Then, an insulator 48 is further stacked on the sacrificial member 47.

The insulators 41, 42, and 48 may contain silicon oxide, and the sacrificial members 43 to 47 may contain silicon nitride. The numbers of layers of the sacrificial members 43 to 47 corresponds to the number of select gate lines SGS, dummy word lines WLd2, word lines WL, dummy word lines WLd1, and select gate lines SGD to be stacked.

Thereafter, a mask having an opening in a region corresponding to the trench structure TST is formed through lithography. A trench is formed through anisotropic etching using the formed mask. The bottom end of the trench reaches the conductor 21. In this process, reactive ion etching (RIE) is adopted for anisotropic etching. Thereafter, an insulator 36 is formed in the trench in such a manner as to fill the trench.

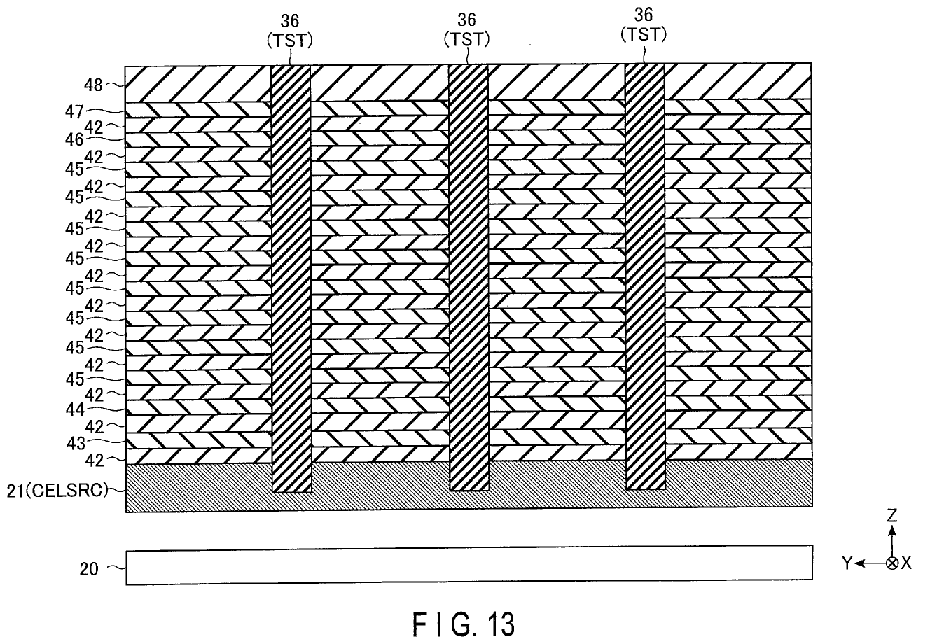

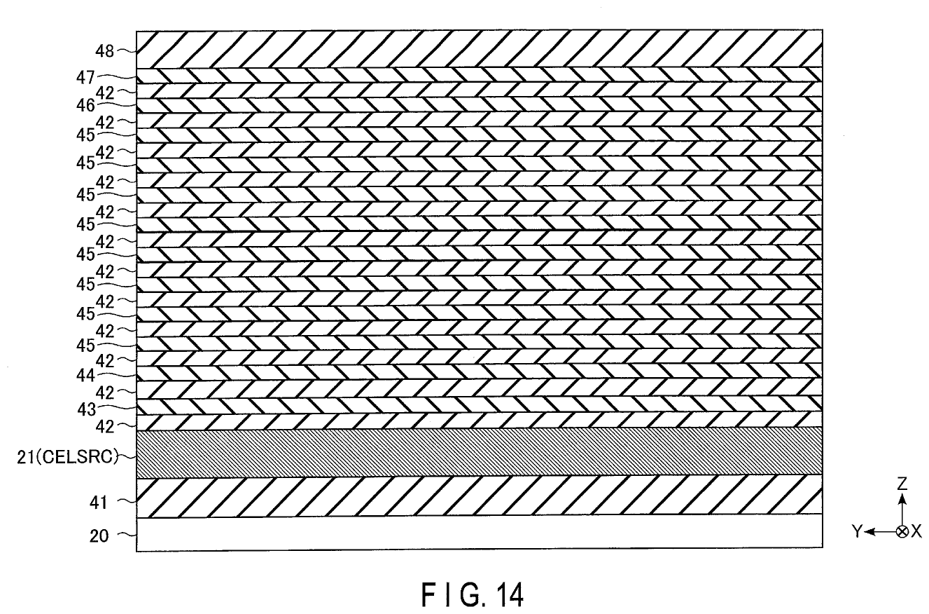

FIG. 13 is a cross-sectional view of the hookup region 200a of the memory cell array 10 taken along line XIII-XIII of FIG. 11. FIG. 14 is a cross-sectional view of the hookup region 200b of the memory cell array 10 taken along line XIV-XIV of FIG. 11.

As illustrated in FIG. 13, three trench structures TST are formed in the layer stack in the hookup region 200a to be aligned in the Y direction. The four regions partitioned by these three trench structures TST are meant to serve as string units SU0, SU2, SU4, and SU6. On the other hand, as illustrated in FIG. 14, no trench structure TST is formed in the layer stack in the hookup region 200b.

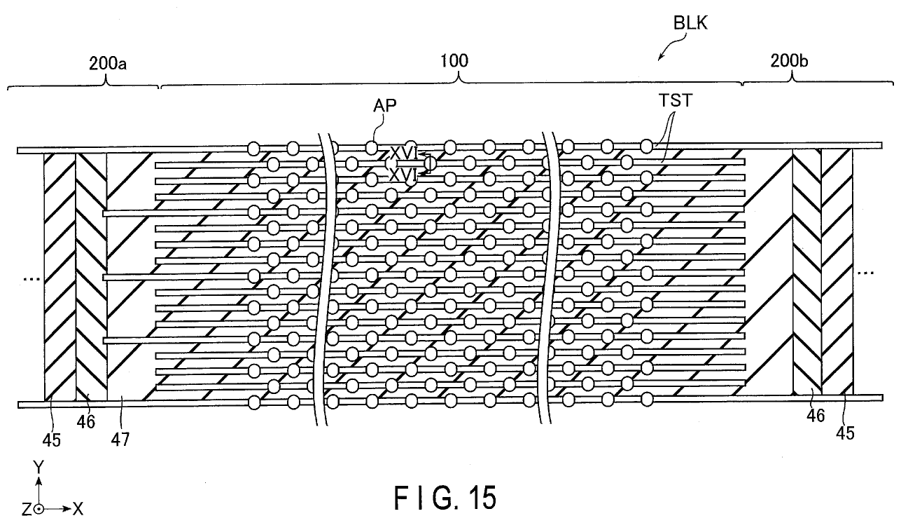

Next, as illustrated in FIG. 15, a plurality of memory pillars AP are formed in the cell region 100 to straddle the trench structures TST.

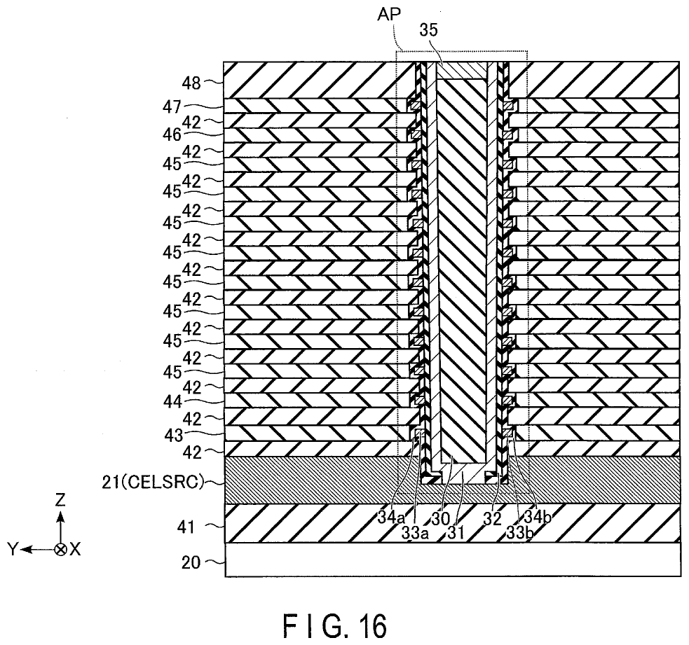

FIG. 16 is a cross-sectional view of a cell region 100 in the memory cell array 10 taken along line XVI-XVI in FIG. 15. As illustrated in FIG. 16, the structure corresponding to the memory strings MSa and MSb as explained with reference to FIG. 5 is formed in a memory pillar AP.

In particular, a mask having an opening in a region corresponding to the memory pillar AP is formed through lithography. Using the formed mask, a hole is formed through anisotropic etching, the bottom end of which may reach the conductor 21. RIE may be adopted for the anisotropic etching in this process. Thereafter, part of the sacrificial members 43 to 47 exposed in the hole may be selectively removed through the hole by wet etching. In this process, recesses are formed through etching in the layers where the sacrificial members 43 to 47 are provided in the hole in such a manner that the top surface of the lowermost insulator 42, the top and bottom surfaces of the insulators 42 except for the lowermost insulator 42, and the bottom surface of the insulator 48 become exposed.

Next, a block insulating film and a charge storage film are sequentially formed in the hole. A recess is not fully filled with the block insulating film, but is fully filled with the charge storage film. Thereafter, part of the charge storage film is isotropically and selectively removed until the insulator 42 becomes exposed. As a result, the charge storage film is separated into the charge storage films 33a and charge storage films 33b, the number of which corresponds to the number of layers of the sacrificial members 43 to 47. After a tunnel insulating film is formed in the hole, the block insulating film and tunnel insulating film at the bottom end of the hole are removed, exposing the conductor 21. This divides the block insulating film into the region 34a corresponding to the memory string MSa and the region 34b corresponding to the memory string MSb.

Thereafter, the semiconductor 31 and core member 30 are formed in the hole for the purpose of filling it. Then, part of the core member 30 is etched back, and the resultant space formed after the etching back is filled with the semiconductor 35. In this manner, a memory pillar AP is formed.

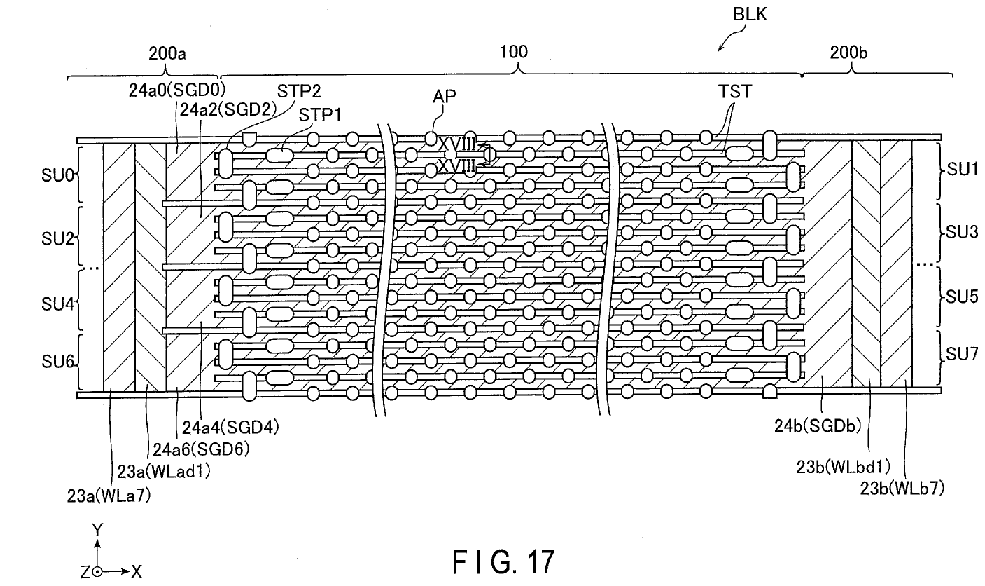

Next, as illustrated in FIG. 17, the sacrificial members 43 are replaced with the conductors 22a and 22b, the sacrificial members 44 to 46 are replaced with the conductors 23a and 23b, and the sacrificial members 45 are replaced with the conductors 24a and 24b.

In particular, a mask having openings in the regions corresponding to the pillars STP1 and STP2 is formed through lithography. Then, using the formed mask, holes are formed through anisotropic etching. The bottom end of each hole may reach the conductor 21. RIE may be adopted for the anisotropic etching of this process. This divides the sacrificial members 43 to 46 into two regions, one corresponding to the string unit SUa and the other corresponding to the string unit SUb. Furthermore, the sacrificial member 47 is separated into five regions corresponding to the string units SU0, SU2, SU4, SU6, and SUb.

Next, the sacrificial members 43 to 47 are selectively removed by wet etching or dry etching through the hole. Then, in the space where the sacrificial members 43 are removed, a conductor 22a is formed in the portion corresponding to the string unit SUa, and a conductor 22b is formed in the portion corresponding to the string unit SUb. In the space where the sacrificial members 44 to 46 are removed, conductors 23a are formed in the portions corresponding to the string unit SUa, and conductors 23b are formed in the portions corresponding to the string unit SUb. In the space where the sacrificial member 47 is removed, a conductor 24a is formed in the portion corresponding to the string unit SUa, and a conductor 24b is formed in the portion corresponding to the string unit SUb. The conductor 24a is formed to include separated portions, namely a portion 24a0 corresponding to the string unit SU0, a portion 24a2 corresponding to the string unit SU2, a portion 24a4 corresponding to the string unit SU4, and a portion 24a6 corresponding to the string unit SU6. Then, pillars STP1 and STP2 are formed by filling the holes with an insulator.

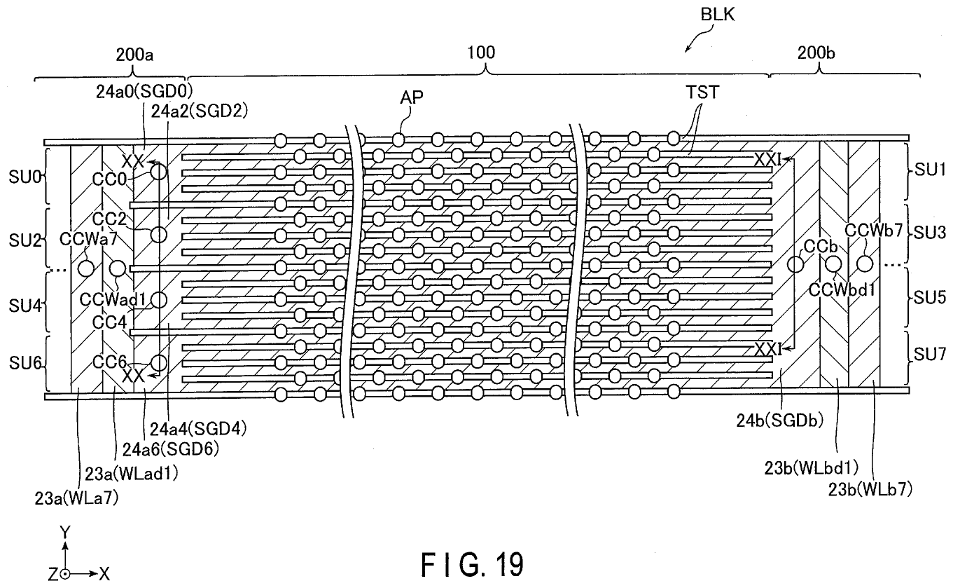

Next, as illustrated in FIG. 19, contacts CC are formed in the hookup regions 200a and 200b to correspond to the conductors in the layer stack.

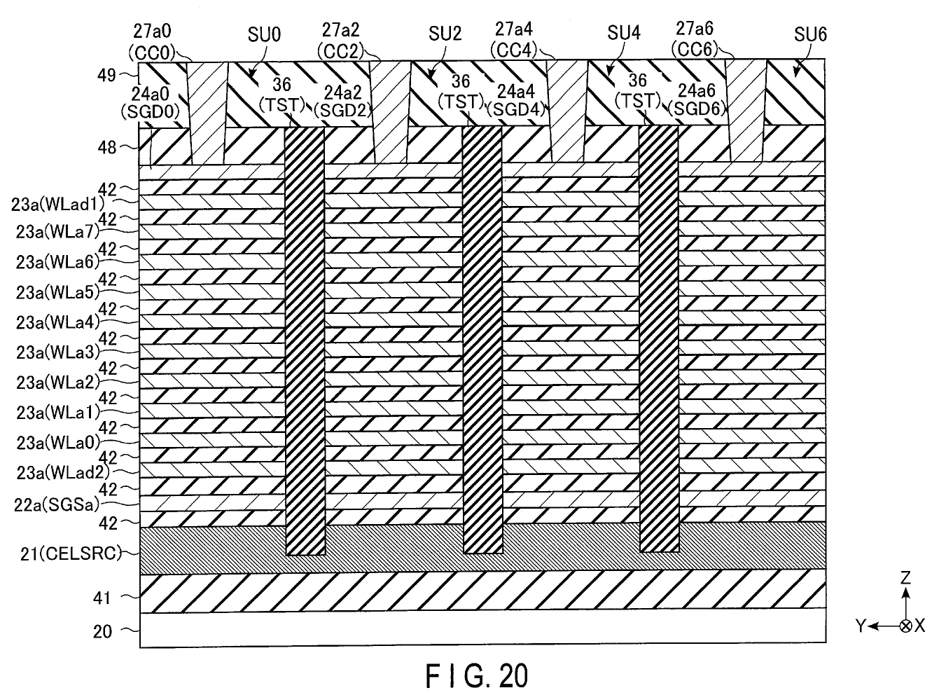

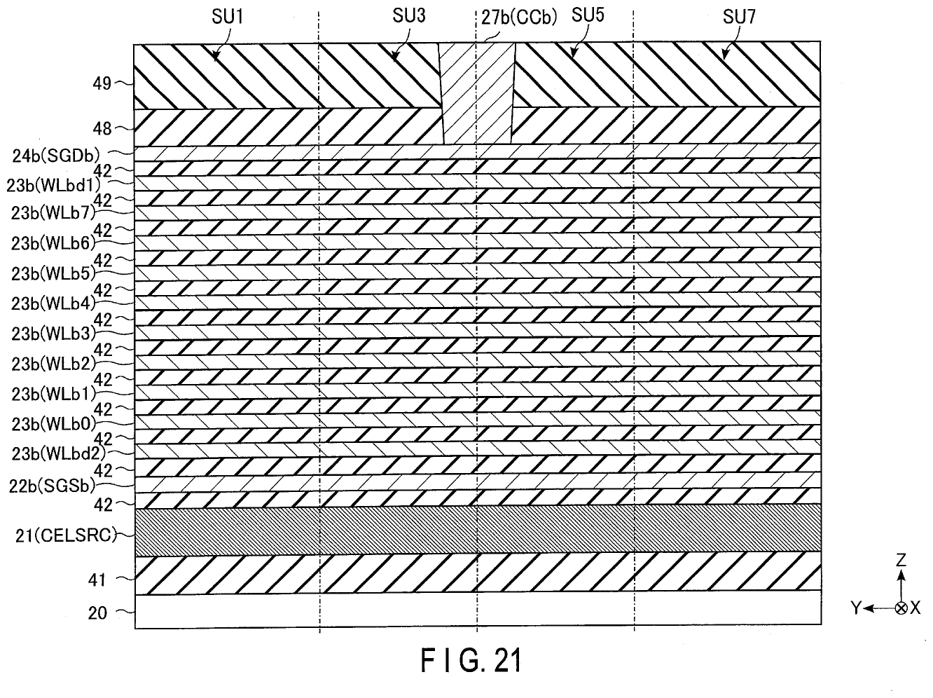

FIG. 20 is a cross-sectional view of the hookup region 200a of the memory cell array 10 taken along line XX-XX of FIG. 19, whereas FIG. 21 is a cross-sectional view of the hookup region 200b of the memory cell array 10 taken along line XXI-XXI of FIG. 19.

As illustrated in FIG. 20, after forming an insulator 49 on the insulator 48, a mask having openings in the regions corresponding to the contacts CC0, CC2, CC4, and CC6 is formed in the hookup region 200a through lithography. Then, using the formed mask, holes are formed through anisotropic etching. The bottom ends of the holes may reach the conductors 24a0, 24a2, 24a4, and 24a6. RIE may be adopted for the anisotropic etching of this process. Thereafter, conductors 27a0, 27a2, 27a4, and 27a6 are formed in the respective holes that reach the conductors 24a0, 24a2, 24a4, and 24a6.

Furthermore, as illustrated in FIG. 21, a mask having an opening in the region corresponding to the contact CCb is formed in the hookup region 200b through lithography, for example concurrently with the process of FIG. 20. Then, using the formed mask, a hole is formed through anisotropic etching. The bottom end of the hole may reach the conductor 24b. RIE may be adopted for the anisotropic etching of this process. Thereafter, conductors 27b are formed in the hole that reach the conductor 24b.

Subsequently, after the process of forming conductors 28a0, 28a2, 28a4, 28a6, and 28b for electrical coupling to the conductors 27a0, 27a2, 27a4, 27a6, and 27b, a memory cell array 10 is provided.

The above-described manufacturing process is a mere example. Other processes may be inserted between the manufacturing steps, or the order of manufacturing steps may be changed as long as no problems arise.

### 1.3 Effects of Present Embodiment

According to the structure of the first embodiment, an increase in the size of a chip can be prevented. This effect is explained below.

The conductors 24a0, 24a2, 24a4, and 24a6 that are hooked up in the hookup region 200a correspond to the string units SU0, SU2, SU4, and SU6, respectively. In contrast, the conductor 24b hooked up in the hookup region 200b is shared by the string units SU1, SU3, SU5, and SU7. Thus, eight string units SU can be controlled by five select gate lines, SGD0, SGD2, SGD4, SGD6, and SGDb, meaning that the number of SGD drivers in the driver module 14 for supplying voltages to the select gate lines SGD can be reduced from eight to five. As a result, an increase in the size of SGD drivers in a chip can be suppressed, as can the overall size of the chip.

To elaborate further, a memory pillar AP includes two memory strings MSa and MSb coupled in parallel between the bit line BL and source line CELSRC. The memory strings MSa and MSb in a memory pillar AP share a semiconductor 31 that serves as a channel. This allows for suitable on/off control of the transistors in the memory strings MSa and MSb, as a result of which an electrical coupling can be established between the transistors of the memory string MSa and the transistors of the memory string MSb. Thus, during a write operation and read operation, the selection transistor STa1 is turned on while the selection transistor STb1 is maintained in the off state to select the memory strings MSb in the string units SU1, SU3, SU5, and SU7. In this manner, even if the select gate line SGDb is shared by the string units SU1, SU3, SU5, and SU7, all the string units SU0 to SU7 of a block BLK can be independently controlled by performing control through the select gate lines SGD0, SGD2, SGD4, and SGD6.

### 2. Second Embodiment

Next, a memory device according to a second embodiment will be explained. In the first embodiment, the string units SU1, SU3, SU5, and SU7 sharing a conductor 24b has been described. The second embodiment differs from the first embodiment in the string units SU1, SU3, SU5, and SU7 having different conductors as a structure corresponding to a conductor 24b. The following explanation will mainly focus on the configuration that differs from the first embodiment.

### 2.1 Layout of Memory Cell Array

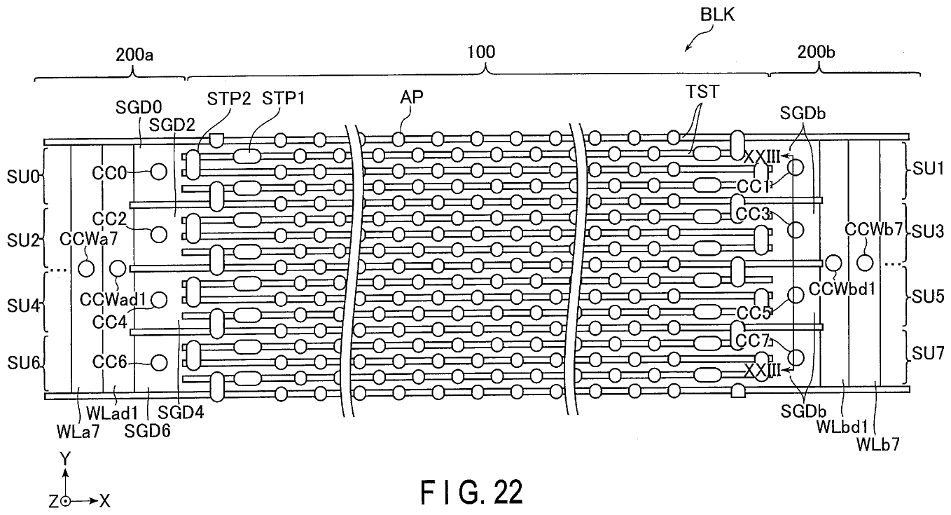

FIG. 22 corresponds to FIG. 4 of the first embodiment, showing an exemplary planar layout of an area corresponding to one block in a memory cell array of the memory device according to the second embodiment.

As illustrated in FIG. 22, in the hookup region 200b, the wiring corresponding to the select gate line SGDb may be separated into four portions by three trench structures TST. The separated four portions correspond to string units SU1, SU3, SU5, and SU7. Contacts CC1, CC3, CC5, and CC7 are provided on the terrace regions of these four portions.

With the above structure, all of the stacked interconnects can be upwardly hooked up from the hookup regions 200 with respect to the memory cell array 10.

### 2.2 Select Gate Line SGDb in Hookup Region

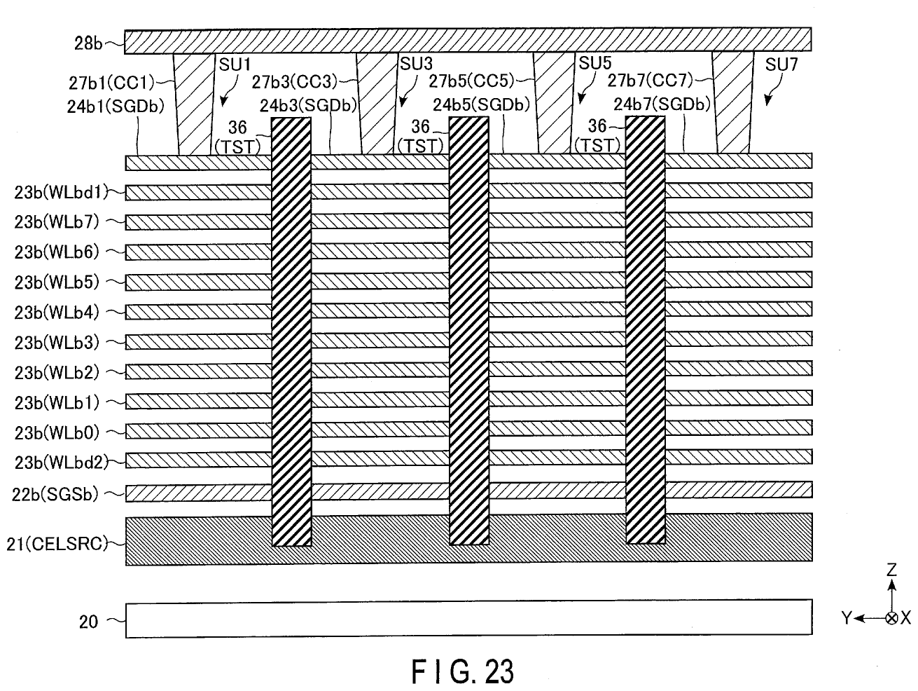

Next, the structure of the select gate line SGDb in the hookup region will be explained with reference to FIG. 23.

FIG. 23 corresponds to FIG. 8 of the first embodiment, showing a cross-sectional view of the hookup region 200b of the memory cell array 10 taken along XXIII-XXIII of FIG. 22. That is, FIG. 23 shows a cross section of the hookup region 200b including contacts CC1, CC3, CC5, and CC7.

As illustrated in FIG. 23, the conductor 24b is separated into conductors 24b1, 24b3, 24b5, and 24b7 by three insulators 36, which each serve as a trench structure TST. The conductors 24b1, 24b3, 24b5, and 24b7 correspond to string units SU1, SU3, SU5, and SU7, respectively.

On the top surfaces of the conductors 24b1, 24b3, 24b5, and 24b7 are conductors 27b1, 27b3, 27b5, and 27b7 arranged to serve as contacts CC1, CC3, CC5, and CC7. A conductor 28b is arranged on the top surfaces of the conductors 27b1, 27b3, 27b5, and 27b7. The conductor 28b is electrically coupled to the SGD driver corresponding to the select gate line SGDb.

With the above structure, even if the conductor 24b is separated for each string unit SU, the five select gate lines SGD0, SGD2, SGD4, SGD6, and SGDb can be electrically coupled to the corresponding SGD drivers in the same manner as in the first embodiment.

### 2.3 Effects of Present Embodiment

In the structure according to the second embodiment, the conductor 24b is separated into four conductors 24b1, 24b3, 24b5, and 24b7 by the trench structures TST. On the top surfaces of the conductors 24b1, 24b3, 24b5, and 24b7 are conductors 27b1, 27b3, 27b5, and 27b7 formed. The hookup regions 200a and 200b are therefore formed to be bilaterally symmetric with respect to the cell region 100. This can reduce a load in designing the memory cell array 10, and can also simplify the manufacturing process.

The top surfaces of the conductors 27b1, 27b3, 27b5, and 27b7 are in contact with a single conductor 28b. This electrically couples the conductors 24b1, 24b3, 24b5, and 24b7 to each other, and their potentials can be controlled by a single SGD driver via a select gate line SGDb. Thus, in the same manner as in the first embodiment, eight string units SU0 to SU7 can be independently controlled by five SGD drivers.

### 3. Third Embodiment

Next, a memory device according to a third embodiment will be explained. In the second embodiment, contacts CC1, CC3, CC5, and CC7 formed to correspond to the string units SU1, SU3, SU5, and SU7, respectively, have been described. The third embodiment differs from the second embodiment in sharing a contact CC among a plurality of string units SU. The following explanation will mainly focus on the configuration that differs from the second embodiment.

### 3.1 Layout of Memory Cell Array

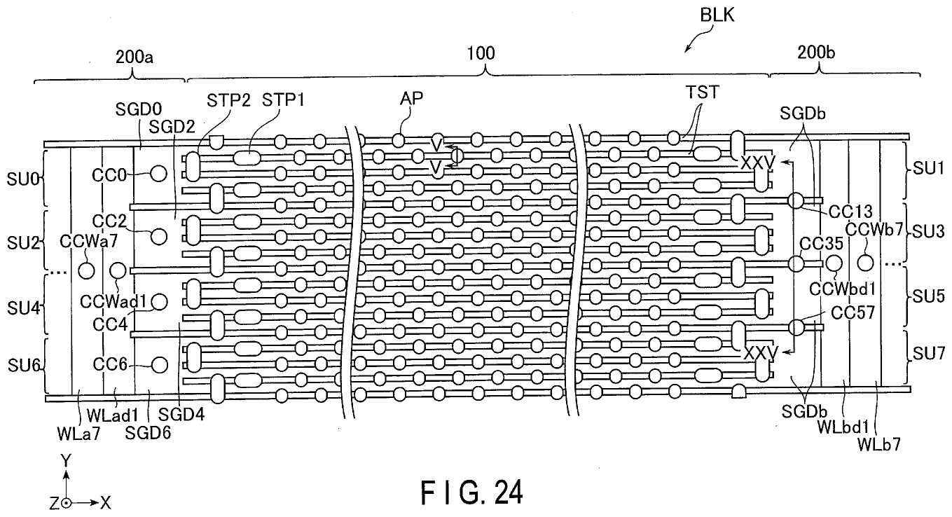

FIG. 24 corresponds to FIG. 22 of the second embodiment, showing an exemplary planar layout of an area corresponding to one block in a memory cell array of the memory device according to the third embodiment.

As illustrated in FIG. 24, in the hookup region 200b, the wiring corresponding to the select gate line SGDb may be separated into four portions by three trench structures TST. The separated four portions correspond to the string units SU1, SU3, SU5, and SU7. A contact CC13 is arranged in such a manner as to straddle a trench structure TST, which separates two portions corresponding to the string units SU1 and SU3 among the four portions, on the terrace regions of these two portions. A contact CC35 is arranged in such a manner as to straddle a trench structure TST, which separates two portions corresponding to the string units SU3 and SU5 among the four portions, on the terrace regions of these two portions. A contact CC57 is arranged in such a manner as to straddle a trench structure TST, which separates two portions corresponding to the string units SU5 and SU7 among the four portions, on the terrace regions of these two portions.

With the above structure, all of the stacked interconnects can be upwardly hooked up from the hookup regions 200 with respect to the memory cell array 10.

### 3.2 Select Gate Line SGDb in Hookup Region

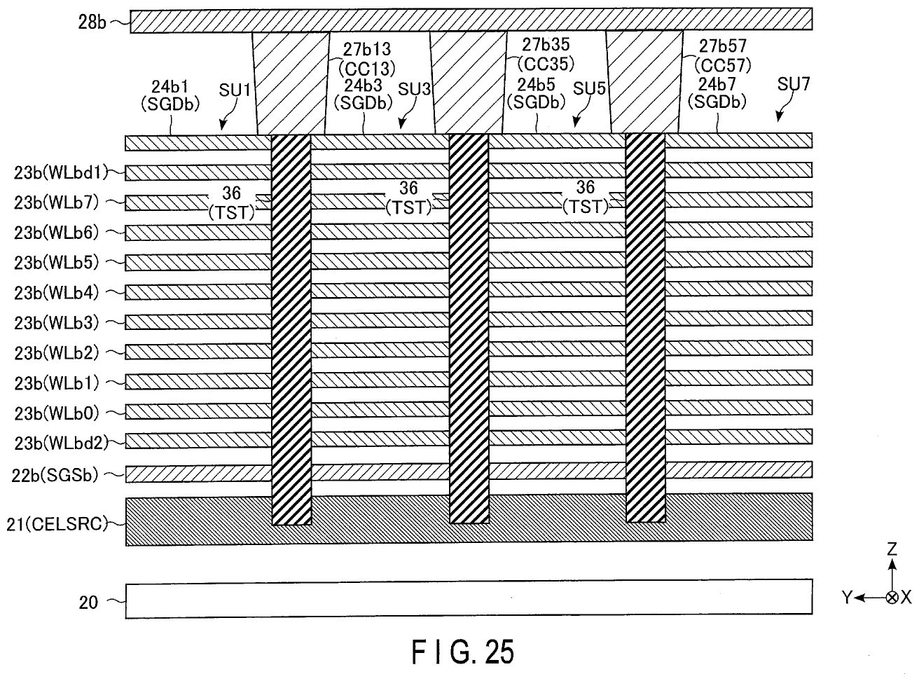

Next, the structure of the select gate line SGDb in the hookup region will be explained with reference to FIG. 25.

FIG. 25 corresponds to FIG. 23 of the second embodiment, showing a cross-sectional view of the hookup region 200b of the memory cell array 10 taken along XXV-XXV of FIG. 24. That is, FIG. 25 shows a cross section of the hookup region 200b including contacts CC13, CC35, and CC57.

As illustrated in FIG. 25, the conductor 24b is separated into conductors 24b1, 24b3, 24b5, and 24b7 by three insulators 36, which each serve as a trench structure TST. The conductors 24b1, 24b3, 24b5, and 24b7 correspond to string units SU1, SU3, SU5, and SU7, respectively.

A conductor 27b13 is arranged on the top surfaces of the conductors 24b1 and 24b3 to serve as a contact CC13 in such a manner as to straddle the insulator 36 that separates the conductors 24b1 and 24b3. A conductor 27b35 is arranged on the top surfaces of the conductors 24b3 and 24b5 to serve as a contact CC35 in such a manner as to straddle the insulator 36 that separates the conductors 24b3 and 24b5. A conductor 27b57 is arranged on the top surfaces of the conductors 24b5 and 24b7 to serve as a contact CC57 in such a manner as to straddle the insulator 36 that separates the conductors 24b5 and 24b7. A conductor 28b is arranged on the top surfaces of the conductors 27b13, 27b35, and 27b57. The conductor 28b is electrically coupled to the SGD driver corresponding to the select gate line SGDb.

With the above structure, even if the conductor 24b is separated for each string unit SU, the five select gate lines SGD0, SGD2, SGD4, SGD6, and SGDb can be electrically coupled to the corresponding SGD drivers in the same manner as in the first embodiment.

### 3.3 Effects of Present Embodiment

In the structure of the third embodiment, the conductor 24b is separated into four conductors 24b1, 24b3, 24b5, and 24b7 by trench structures TST. A conductor 27b13 is formed on the top surfaces of the conductors 24b1 and 24b3, a conductor 27b35 is formed on the top surfaces of the conductors 24b3 and 24b5, and a conductor 27b57 is formed on the top surfaces of the conductors 24b5 and 24b7. The top surfaces of the conductors 27b13, 27b35, and 27b57 are in contact with a single conductor 28b. In this manner, the conductors 24b1, 24b3, 24b5, and 24b7 can be electrically coupled to each other, and their potentials can be controlled by a single SGD driver via a select gate line SGDb. Thus, in the same manner as in the first embodiment, eight string units SU0 to SU7 can be independently controlled by five SGD drivers.

### 4. Others

Various modifications may be made to the above first to third embodiments.

For instance, according to the first to third embodiments, the charge storage films 33a and 33b formed in the memory strings MSa and MSb in a separated manner for each layer have been described, but this is not a limitation. The charge storage films 33a and 33b may be formed as continuous films in the memory strings MSa and MSb, respectively. In addition, the charge storage films 33a and 33b in one memory pillar AP may be formed as a continuous film. In this case, a charge trapping-type material (e.g., silicon nitride) will be selected for the charge storage film instead of a floating gate-type material.

In the above third embodiment, a single conductor 27b (e.g., 27b13) arranged for two portions of a conductor 24b (e.g., 24b1 and 24b3) corresponding to two string units SU has been explained, but this is not a limitation. For instance, a single conductor 27b may be arranged for three or more portions of a conductor 24b corresponding to three or more string units.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit.

What is claimed is:

1. A memory device comprising:
a plurality of first conductors stacked along a first direction;
a second conductor, a third conductor, and a fourth conductor stacked in a same layer above the first conductors;
a plurality of fifth conductors stacked along the first direction;
a sixth conductor stacked above the fifth conductors;
a first semiconductor extending along the first direction between the second conductor and the sixth conductor;
a second semiconductor extending along the first direction between the third conductor and the sixth conductor; and
a third semiconductor extending along the first direction between the fourth conductor and the sixth conductor.

2. The memory device according to claim 1, further comprising:
a first charge storage film between the second conductor and the first semiconductor;
a second charge storage film between the sixth conductor and the first semiconductor;
a third charge storage film between the third conductor and the second semiconductor;
a fourth charge storage film between the sixth conductor and the second semiconductor;
a fifth charge storage film between the fourth conductor and the third semiconductor; and
a sixth charge storage film between the sixth conductor and the third semiconductor.

3. The memory device according to claim 2, wherein
the first charge storage film is separated from the second charge storage film,
the third charge storage film is separated from the fourth charge storage film, and
the fifth charge storage film is separated from the sixth charge storage film.

4. The memory device according to claim 2, wherein
the first charge storage film is continuous to the second charge storage film,
the third charge storage film is continuous to the fourth charge storage film, and
the fifth charge storage film is continuous to the sixth charge storage film.

5. The memory device according to claim 1, wherein
the second conductor, the third conductor, the fourth conductor, and the sixth conductor are electrically insulated.

6. The memory device according to claim 1, further comprising:
a first contact in contact with a top surface of the second conductor;
a second contact in contact with a top surface of the third conductor;
a third contact in contact with a top surface of the fourth conductor; and
a fourth contact in contact with a top surface of the sixth conductor.

7. A memory device comprising:
a plurality of first conductors stacked along a first direction;
a second conductor and a third conductor stacked on a same layer above the first conductors;
a plurality of fifth conductors stacked along the first direction;
a sixth conductor and a seventh conductor stacked on a same layer above the fifth conductors;
a first semiconductor extending along the first direction between the second conductor and the sixth conductor;
a second semiconductor extending along the first direction between the third conductor and the sixth conductor;
a third semiconductor extending along the first direction between the third conductor and the seventh conductor; and
a contact in contact with a top surface of the sixth conductor and a top surface of the seventh conductor.

8. The memory device according to claim 7, further comprising:
a first charge storage film between the second conductor and the first semiconductor;
a second charge storage film between the sixth conductor and the first semiconductor;
a third charge storage film between the third conductor and the second semiconductor;
a fourth charge storage film between the sixth conductor and the second semiconductor;
a fifth charge storage film between the third conductor and the third semiconductor; and
a sixth charge storage film between the seventh conductor and the third semiconductor.

9. The memory device according to claim 8, wherein
the first charge storage film is separated from the second charge storage film,
the third charge storage film is separated from the fourth charge storage film, and
the fifth charge storage film is separated from the sixth charge storage film.

10. The memory device according to claim 8, wherein
the first charge storage film is continuous to the second charge storage film,
the third charge storage film is continuous to the fourth charge storage film, and
the fifth charge storage film is continuous to the sixth charge storage film.

11. The memory device according to claim 7, wherein
the second conductor, the third conductor, and the contact are electrically insulated.

12. A memory device comprising:
a plurality of first conductors stacked along a first direction;
a second conductor and a third conductor stacked on a same layer above the first conductors;
a plurality of fifth conductors stacked along the first direction;
a sixth conductor and a seventh conductor stacked on a same layer above the fifth conductors;
a first semiconductor extending along the first direction between the second conductor and the sixth conductor;
a second semiconductor extending along the first direction between the third conductor and the sixth conductor;
a third semiconductor extending along the first direction between the third conductor and the seventh conductor;
a first contact in contact with a top surface of the sixth conductor;
a second contact in contact with a top surface of the seventh conductor; and
an eighth conductor in contact with a top surface of the first contact and a top surface of the second contact.

13. The memory device according to claim 12, further comprising:
a first charge storage film between the second conductor and the first semiconductor;
a second charge storage film between the sixth conductor and the first semiconductor;
a third charge storage film between the third conductor and the second semiconductor;
a fourth charge storage film between the sixth conductor and the second semiconductor;
a fifth charge storage film between the third conductor and the third semiconductor; and
a sixth charge storage film between the seventh conductor and the third semiconductor.

14. The memory device according to claim 13, wherein
the first charge storage film is separated from the second charge storage film,
the third charge storage film is separated from the fourth charge storage film, and
the fifth charge storage film is separated from the sixth charge storage film.

15. The memory device according to claim 13, wherein
the first charge storage film is continuous to the second charge storage film,
the third charge storage film is continuous to the fourth charge storage film, and
the fifth charge storage film is continuous to the sixth charge storage film.

16. The memory device according to claim 12, wherein
the second conductor, the third conductor, and the eighth conductor are electrically insulated.
